(19) United States
(12) Patent Application Publication
(10) Pub. No.: US 2006/0227585 A1
(43) Pub. Date: Oct. 12, 2006

(54) Computer system, disk apparatus and data update control method

(76) Inventor: Masanori Tomoda, Kokubunji-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/378,475

(22) Filed: Mar. 20, 2006

(30) Foreign Application Priority Data
Mar. 24, 2005 (JP) 2005-086359

(51) Int. Cl. G11C 19/08

(52) U.S. Cl. 365/36

(57) ABSTRACT

A computer system includes a disk apparatus and a host computer including a journal file system. The disk apparatus includes a memory unit which is capable of permanently storing a journal, a storing control unit which stores a journal, which is sent from the host computer, in the memory unit, and an updating unit which executes data update corresponding to the journal stored in the memory unit in accordance with an instruction from the host computer. The journal file system of the host computer includes a writing unit which executes, each time the data on the disk apparatus is updated, writing of a journal, which corresponds to the data update, to the disk apparatus, and an informing unit which informs the disk apparatus of an instruction to execute the data update corresponding to the written journal.

### CROSS-REFERENCE TO RELATED APPLICATIONS

This application is based upon and claims the benefit of priority from prior Japanese Patent Application No. 2005-086359, filed Mar. 24, 2005, the entire contents of which are incorporated herein by reference.

### BACKGROUND OF THE INVENTION

1. Field of the Invention

The present invention relates to a data update control technique in a computer system including a journal file system that ensures the data integrity.

2. Description of the Related Art

In recent years, with an increasing polarity of the Internet, most of works, which relate to transactions between a company and a customer or transactions between companies, have been computerized. The computerization of transactions requires high reliability and high responsivity in storage apparatuses that store various data.

A RAID system enables two or more disk drives to act as one logical volume, and provides high reliability and performance. There have been proposed other various techniques for enhancing the responsivity in the RAID system (see, for instance, Jpn. Pat. Appln. KOKAI Publications Nos. 11-53235 and 2001-75741).

On the other hand, various techniques have been developed for maintaining the consistency of a file system even if fault occurs in a computer system that comprises a storage apparatus, to which the RAID system, for example, is applied, and a host computer that stores data in the storage apparatus. A journal system is one of these techniques.

In the journal file system, file system metadata is to be updated, data contents before and during the update are recorded in a journal. Thereby, even in case of a system halt due to accidental power failure, etc., when the system is restarted, the data, which was being updated at the time of system halt, can be specified on the journal and can quickly be recovered to the consistent state.

There has been proposed another method in which not only metadata but also user data is included in the journal. In this method, in case of power failure or system halt, the integrity of the data can also be ensured.

In the method in which both the metadata and user data are stored in the journal, after the metadata and user data are written in a disk as journals, the actual metadata and user data are further written in the disk. This two-stage write provides Atomicity: a single user data write operation is completed successfully or cancelled with no changes. If the write of actual metadata and user data is directly attempted and it fails, it would be impossible to recover the data that was lost due to incomplete write (i.e. the data that was changed with update data).

For this reason, in this method, the metadata and user data are written twice in the disk. Thus, there is such a problem that the amount of data transfer to the disk is doubled, compared to an ordinary file system that does not use the journal, and that write has to been executed twice in the process. In the prior art including the above-mentioned Jpn. Pat. Appln. KOKAI Publications Nos. 11-53235 and 2001-75741, attention is paid to how to meet the demand for high reliability and high responsivity with respect to individual write operations. No attention is paid to the enhancement in the efficiency of write in the whole system to which the file system that stores both metadata and user data in the journal is applied.

### BRIEF SUMMARY OF THE INVENTION

The present invention has been made in consideration of the above-described problems, and the object of the invention is to provide a computer system, a disk apparatus and a data update control method, which enhance the write performance of a journal system, which records user data as a journal, while high reliability of the journal system is being maintained.

In order to achieve the object, according to an aspect of the present invention, there is provided a computer system including a disk apparatus and a host computer including a journal file system which records a journal in the disk apparatus in a pre-process, the journal including update data for ensuring data integrity on the disk apparatus when the data on the disk apparatus is updated, the disk apparatus including a memory unit which is capable of permanently storing the journal, a storing control unit configured to store a journal, which is sent from the host computer, in the memory unit, and a updating unit configured to execute data update corresponding to the journal stored in the memory unit in accordance with an instruction from the host computer, and the journal file system of the host computer including a writing unit configured to execute, each time the data on the disk apparatus is updated, writing of a journal, which corresponds to update data, to the disk apparatus, and a informing unit configured to inform the disk apparatus of an instruction to execute the data update corresponding to the written journal.

According to another aspect of the present invention, there is provided a computer system including a disk apparatus and a host computer including a journal file system which records a journal in the disk apparatus in a pre-process, the journal including update data for ensuring data integrity on the disk apparatus when the data on the disk apparatus is updated, the disk apparatus including a conversion map which stores correspondency between a logical address on a disk and a physical address on the disk, a storing control unit configured to store a journal, which is sent from the host computer, in an empty area on the disk, on which data update corresponding to the journal is executed, and a operating unit configured to operate the conversion map based on an instruction from the host computer, in order to change the update data which is included in the journal stored in the empty area on the disk into actual update data, and the journal file system of the host computer including a writing unit configured to execute, each time the data on the disk apparatus is updated, writing of a journal, which corresponds to the data update, to the disk apparatus, and a informing unit configured to inform the disk apparatus of an instruction to execute the data update corresponding to the written journal.

The present invention can provide a computer system, a disk apparatus and a data update control method, which enhance the write performance of a journal system, which records user data as a journal, while high reliability of the journal system is being maintained.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 shows the configuration of a computer system according to a first embodiment of the present invention;

FIG. 2 is a flow chart illustrating a specific process procedure of a commit process that is executed by the computer system of the first embodiment;

FIG. 3 shows the structure of a journal which is recorded in the computer system of the first embodiment;

FIG. 4 is a flow chart illustrating a specific process procedure of a checkpoint process which is executed by the computer system of the first embodiment;

FIG. 5 is a flow chart illustrating a detailed procedure of a write process for writing journal content in a disk, which is executed by the computer system of the first embodiment;

FIGS. 6A and 6B are views for illustrating a scheme in which data transfer is reduced in the computer system of the first embodiment;

FIG. 7 is a flow chart illustrating a specific process procedure of a recovery process, which is executed by the computer system of the first embodiment;

FIG. 8 shows the configuration of a modification of the computer system of the first embodiment;

FIG. 9 shows the configuration of a computer system according to a second embodiment of the invention;

FIG. 10 shows an example of entries in a conversion map, which is used in the computer system of the second embodiment; and

FIG. 11 is a flow chart of a process relating to the conversion map, which is executed by a disk control unit of the computer system of the second embodiment.

### DETAILED DESCRIPTION OF THE INVENTION

Embodiments of the present will be described with reference to the accompanying drawings.

### FIRST EMBODIMENT

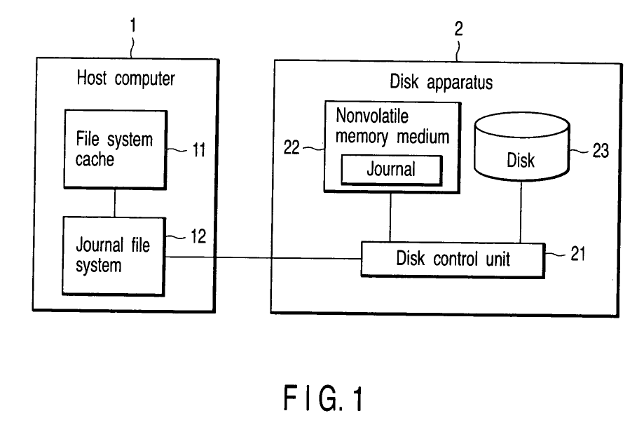

A first embodiment of the invention is described. FIG. 1 shows the configuration of a computer system according to the first embodiment.

A host computer 1 includes a journal file system, application programs, a memory management function, a process management function, a network management function, and a device driver for managing connection to a disk apparatus. FIG. 1 shows only a file system cache 11 and a journal file system 12, which relate to the description of the first embodiment.

The host computer 1 is connected to a disk apparatus 2 by a bus, such as SCSI bus or fibre channel, or by a transfer medium. The host computer 1 recognizes the disk apparatus 2 as a block device, and accesses it.

The file system cache 11 is provided on the memory of the host computer 1, and is used as a cache for data that is present on the disk apparatus 2. The journal file system 12 is a file system that processes access requests from the application programs and operating system to the disk. Upon receiving an access request, the journal file system 12 accesses the file system cache 11 or disk apparatus 2 according to the access request and returns a response.

On the other hand, the disk apparatus 2 includes a disk control unit 21, a nonvolatile memory medium 22 and a disk 23. The disk control unit 21 receives an access command, such as a SCSI command, from the host computer 1, access to the disk 23, and returns a response to the host computer 1.

The nonvolatile memory medium 22 stores control information including a file operation and data, which is called “journal”. A memory, whose content would not be lost even in case of power failure, etc., is used as the memory medium 22. For instance, a nonvolatile memory medium, such as an NVRAM, or a battery-backed-up memory, is usable as the memory medium 22. In short, any type of memory, which can permanently store data, can be used. In this description, the term “nonvolatile memory medium” is used for the purpose of easier understanding.

In the computer system of the present embodiment, the process relating to the file system is not essential. Thus, the description below is focused on the processes relating to the journal.

The processes relating to the journal include the following principal processes:
(1) A process for updating data of a file or file system metadata,
   (a) Generation and write of a journal to the disk when an operation is executed on a file (commit process),
   (b) Reflection of actual data on the disk (checkpoint process), and
(2) Recovery of a file system on the basis of a journal after accidental power failure (recovery process).

These processes will be explained below.

* Commit Process

The commit process is a process for writing an update component of disk data, which is generated as a result of a file operation, into a journal. When data of a file or file system metadata update is completed, result of the requested operation is finally committed by the commit process. Even in case of accidental power failure or crash, the result of the requested operation is surely reflected.

In usual cases, update data is stored in a nonvolatile memory medium which is not affected by power failure, etc. Thereby, the commit process is executed. It is not necessary that the update data is reflected on an actual disk. Such data may be stored in any form if the date maintains consistency with subsequent process operations and is not lost by power failure, etc.

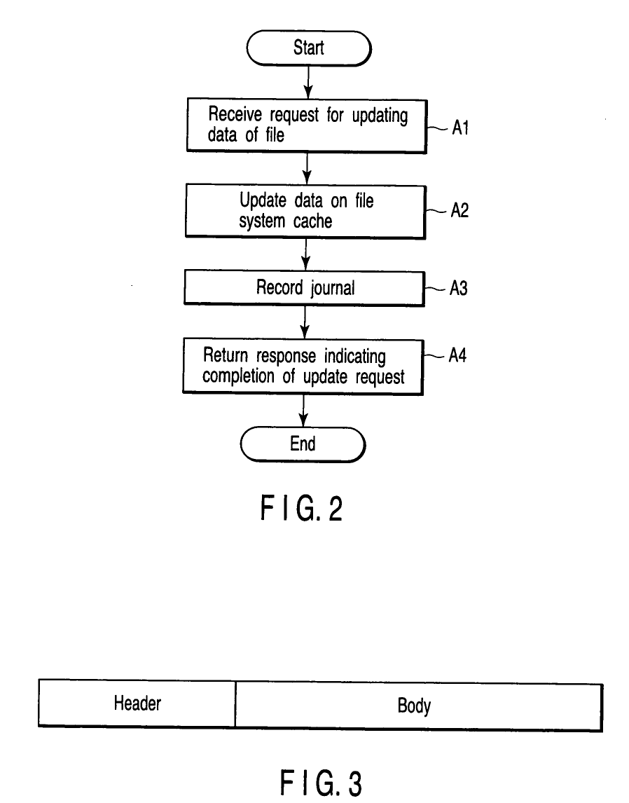

FIG. 2 is a flow chart illustrating a specific process procedure of the commit process.

If the journal file system 12 of the host computer 1 receives an update request to make an update to a file (step A1), the journal file system 12 first updates data on the file system cache 11 that is provided on the memory of the host computer 1 (step A2). Then, the journal file system 12 instructs the disk control unit 21 of the disk apparatus 2 to store, as a journal, the data of the disk apparatus 2, which is to be changed by the operation in step A1. On the other hand, the disk control unit 21 of the disk apparatus 2, which has received this instruction, stores the journal in the nonvolatile memory medium 22 (step A3). The journal file system 12 returns a response, which indicates the completion of the operation, in connection with the operation in step A1 (step A4).

The data in the file system cache 11 will be reflected on the disk apparatus 2 by a checkpoint process, which is to be described later. Unlike an ordinary file system, no such a process is executed as to output the data in the file system cache 11 to the disk at a proper timing.

As regards power failure that may occur before the process of steps A1 to A3 is completed, a response indicating the completion of the operation has not yet been returned, nor has the processing of data on the disk not been interrupted in the complete state. Thus, there arises no problem even if the result of data process operation is not reflected on the disk. On the other hand, the data is recorded on both the cache and the journal during the time period from the completion of the process of step A3 to the completion of the checkpoint process (to be described later). In this case, if power failure occurs, the data on the file system cache 11 would be lost. However, as will be described later, the data itself is not lost since the operation of step A1 is reflected in the disk apparatus 2 by updating the data on the disk on the basis of the journal that is stored in the nonvolatile memory medium 22.

FIG. 3 shows the structure of the journal that is recorded in step A3. As is shown in FIG. 3, the journal comprises a header and a body. The header stores record information relating to the position on the disk apparatus 2 and the size of the data that is stored in the body of the journal. On the other hand, the body stores the image of a block, which is to be stored in the disk apparatus 2. Thus, the body is composed of a multiple size of data of a minimum access unit (e.g. a sector in the case of the disk) for access to the disk apparatus 2.

* Checkpoint Process

The checkpoint process is a process for reflecting the result of an operation request to a file system or a file on the actual location of disk apparatus 2. In the prior art, in the checkpoint process, the data in the file system cache 11 is written in the disk apparatus 2, and thereby the data in the disk apparatus 2 is made to correspond to the result of the process operation. By contrast, in the computer system of the present embodiment, in the checkpoint process, the disk control unit 21 of the disk apparatus 2 refers to the data of the journal and executes write in the disk. Thereby, the data transfer between the host computer 1 and disk apparatus 2 is reduced. This point characterizes the computer system of the present embodiment.

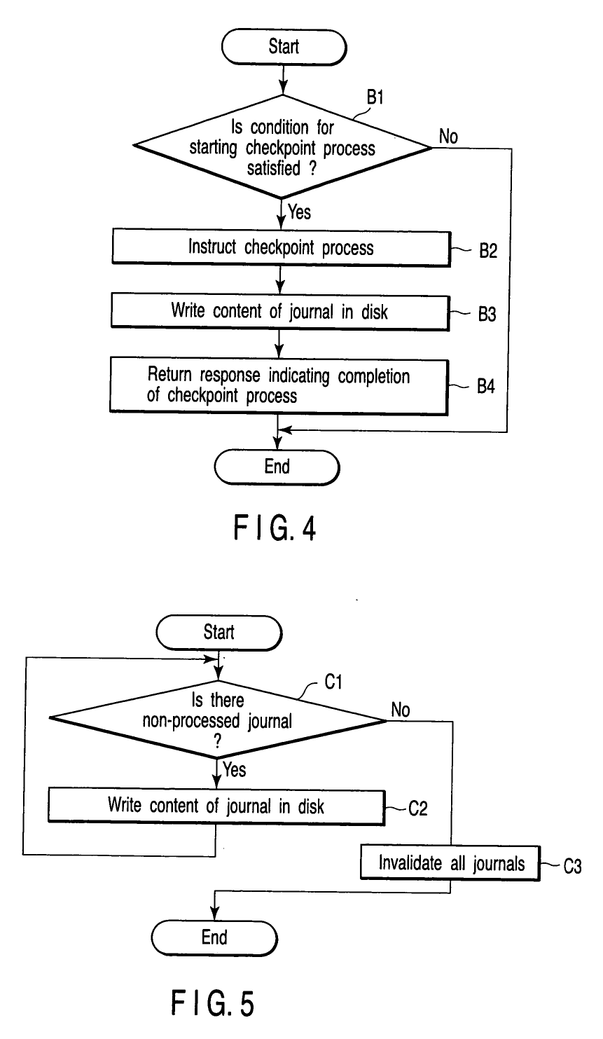

FIG. 4 is a flow chart illustrating a specific process procedure of the checkpoint process.

To start with, the journal file system 12 of the host computer 1 checks whether a condition for starting the checkpoint process is satisfied (step B1). Examples of the condition for starting the checkpoint process are as follows.

(1) A journal storage area is full, and no more journals can be stored.

This condition is necessary in order to create an empty space in the journal area, since the lack in the empty space disables the execution of the operation request to the file system or file.

(2) No empty space exists in the file system cache.

Like the above (1), the lack in the empty space disables the execution of the operation request to the file system or file.

(3) Others (e.g. the passing of predetermined time intervals).

From the standpoint of reliability, the matching of data in the disk needs to be maintained, for example, at predetermined time intervals.

If any one of the above conditions for starting the checkpoint process is satisfied (YES in step B1), the journal file system 12 instructs the disk control unit 21 of the disk apparatus 2 to execute the checkpoint process (step B2). On the other hand, upon receiving the instruction, the disk control unit 21 writes the contents, which correspond to all journals stored in the nonvolatile memory medium 22, into the disk 23 (step B3), and returns a response indicating the completion of the checkpoint process (step B4).

FIG. 5 is a flow chart illustrating a detailed procedure of the process of writing the content of the journal into the disk 23, which is executed in step B3.

To start with, the disk control unit 21 checks whether there is a non-processed journal which is yet to be processed (step C1). If there is a non-processed journal (YES in step C1), the disk control unit 21 refers to the header of the non-processed journal and writes the data, which is stored in the body, into the disk 23 in accordance with the data position on the disk 23 and the data size (step C2). The disk control unit 21 repeats the process beginning with step C1, as long as there remains a non-processed journal. If there is no non-processed journal (NO in step C1), the disk control unit 21 records the invalidity of the data in all journals (step C3). This is executed in order to complete the data matching process for the disk.

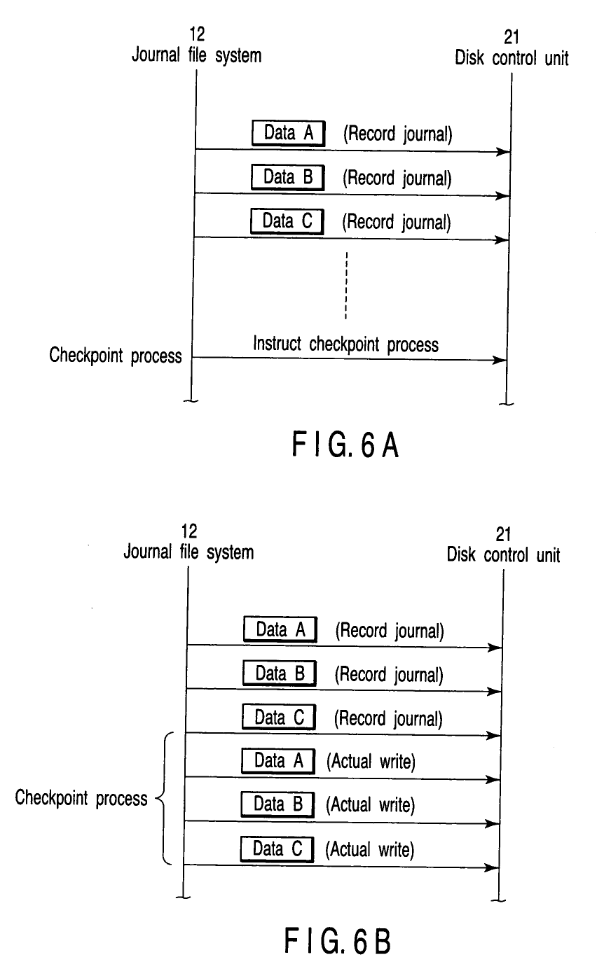

Specifically, by executing the checkpoint process according to this procedure, the data transfer between the host computer 1 and disk apparatus 2 can be reduced. FIGS. 6A and 6B are views for illustrating a scheme in which data transfer is reduced in the computer system of the present embodiment. FIG. 6A illustrates data transfer in the case where the checkpoint process is executed according to the above-described procedure, and FIG. 6B illustrates data transfer in the case where the checkpoint process is executed according to the conventional procedure. As shown in FIG. 6A and FIG. 6B, in the prior art, when the checkpoint process is to be executed, all the data that have been written up to that time point need to be re-transferred. By contrast, in the computer system of the present embodiment, it should suffice if the journal file system 12 transfers to the disk control unit 21 only a notice to instruct execution of the checkpoint process.

In this example, the journal is stored in the nonvolatile memory medium 22. Even if the journal is stored in the disk 23, apart from the actual data, the data update control method of the computer system of the present invention can effectively be implemented.

* Recovery Process

The recovery process is a process for recovering the condition in which the operation process to the file system or file is not completely finished due to accidental power failure, system halt, etc. The journal file system 12 executes the recovery process by writing the data, which is recorded as the journal, into the disk apparatus 2. In normal cases, the recovery process is executed when it is detected at the time of start-up that the completing process was not normally executed at the time of the previous operation.

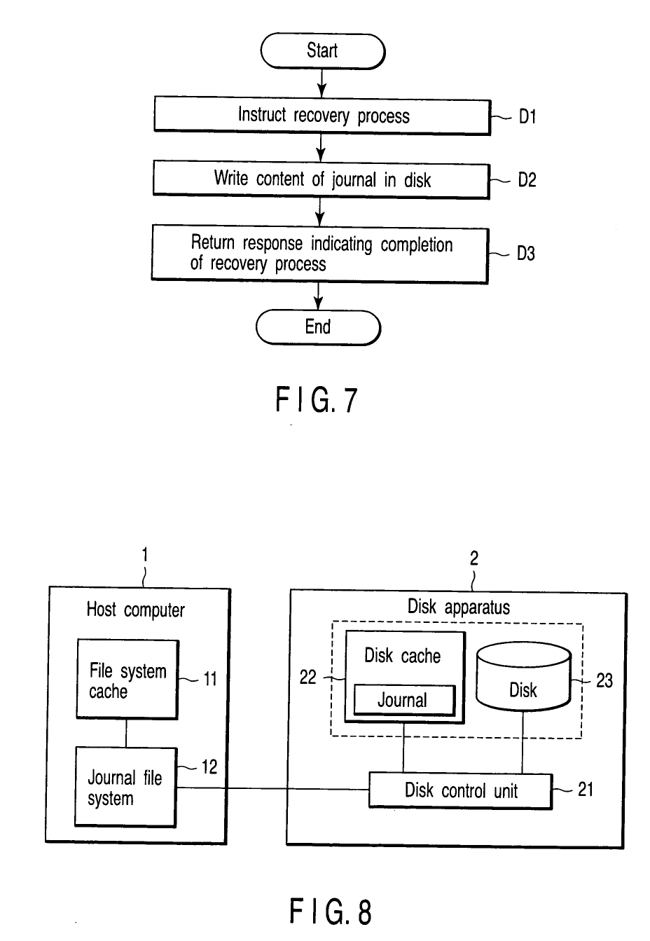

FIG. 7 is a flow chart illustrating a specific process procedure of the recovery process.

To start with, the journal file system 12 of the host computer 1 instructs the disk control unit 21 of the disk apparatus 2 to execute the recovery process (step D1). On the other hand, upon receiving the instruction, the disk control unit 21 writes the contents, which correspond to all journals stored in the nonvolatile memory medium 22, into the disk 23 (step D2). Then, the disk control unit 21 returns a response indicating the completion of the recovery process (step D3). The process of writing the journals in the disk, which is executed in step D2, is the same as the operation process in step B3 in FIG. 4, which has been described in connection with the checkpoint process.

As has been described above, according to the computer system of the present embodiment, while the high reliability of the journal system, which records user data as journals, is being maintained, the efficiency of the journal system can be enhanced.

In the meantime, in usual cases, the disk apparatus 2 includes a cache for storing data that is to be written in the disk 23. In order to enhance the reliability of the disk apparatus 2, a measure is taken to prevent lost of data in the cache due to power failure, etc., and to protect the data in the cache. Thus, as shown in FIG. 8, it is effective, as a modification of the embodiment, to assign the cache to the nonvolatile memory medium 22. That is, the area of the nonvolatile memory medium 22, which stores journals, is also used as the cache for the disk 23.

In this modification, attention is paid to the fact that the journal and the disk cache are present on the same nonvolatile memory medium. This modification aims at quickly executing the write process for writing journals in the disk 23. To be more specific, in the write process for writing journal data by the disk control unit 21 within the disk apparatus 2, the journal data on the nonvolatile memory medium 22 is not written again in the disk 23, but the journal data is made to remain as such in the area of the disk cache. This is realized by causing the disk control unit 21 to update management data (e.g. disk cache directory) for managing the area of the disk cache.

The journal data, which is managed as the disk cache, is written in the disk 23 with a delay, in the same manner as in the case where ordinary cache data is written in the disk. Even in case of accidental power failure, etc, the disk control unit 21 executes a process for establishing matching between the data in the cache and the data in the disk as a recovery process for cache data.

As has been described above, by converting the journal data to the disk cache data, the checkpoint process can be executed at high speed without the need to wait for the completion of the process for actually writing journal data in the disk.

### SECOND EMBODIMENT

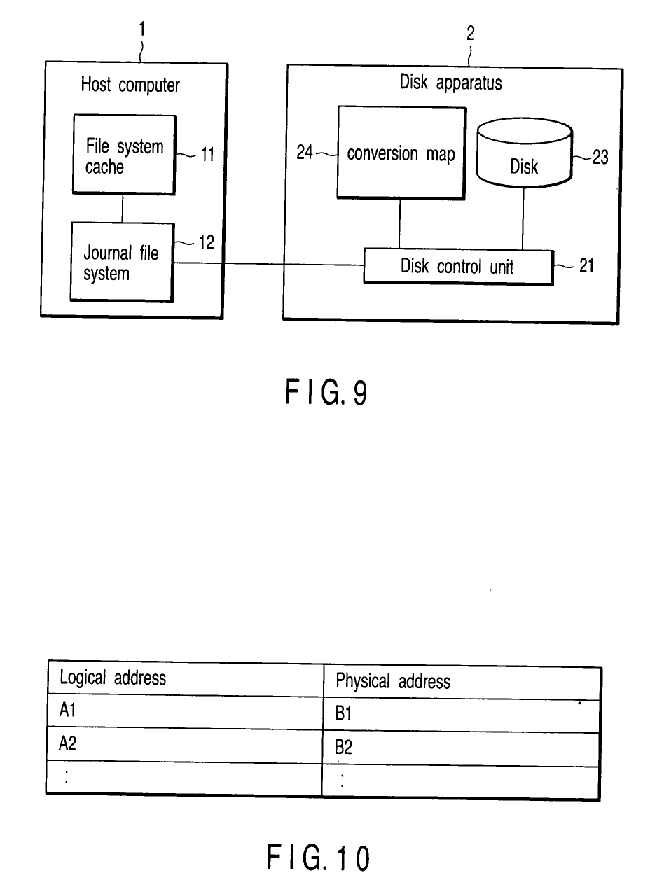

Next, a second embodiment of the invention is described. FIG. 9 shows the configuration of a computer system according to the second embodiment.

In the computer system of the first embodiment, it should suffice if journals are present in the nonvolatile memory medium, and it is not necessary that the journals be stored on the disk 23 as files. On the other hand, in the computer system of the second embodiment, journals are stored on the disk 23 as files, in order to cope with the case in which the amount of update data is so large that the amount of journals becomes very large. Thus, in the computer system of the second embodiment, it does not matter whether the nonvolatile memory medium, which is used as a cache, is present in the disk apparatus 2 or not.

To begin with, a description is given of a conversion map 24 and the operational principle of the disk control unit 21 in the computer system of the second embodiment, which uses the conversion map 24.

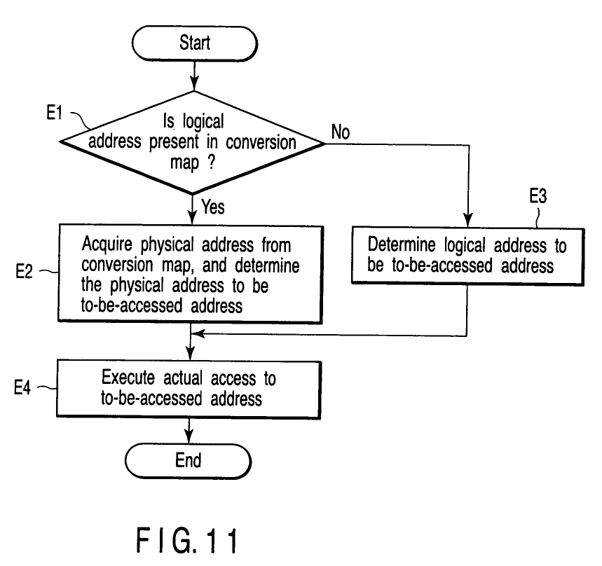

The conversion map 24 stores addresses (logical addresses) of the disk 23, which is accessed from the host computer 1, and actual storage positions (physical addresses) on the disk 23. Normally, the logical addresses correspond to the physical addresses. In a case where the conversion map 24 includes entries as shown in FIG. 10, data at logical address A1 is stored at physical address B1. Thus, as regards access to logical address A, the disk control unit 21 actually executes access to physical address B. FIG. 11 is a flow chart illustrating the process of the disk control unit 21, which relates to the conversion map 24.

The disk control unit 21 checks whether a logical address is present in the conversion map 24 (step E1). If the logical address is present (YES in step E1), the disk control unit 21 acquires a corresponding physical address from the conversion map 24, and determines the physical address to be a to-be-accessed address (step E2). If a logical address is not present in the conversion map 24 (NO in step E1), the disk control unit 21 determines the logical address to be a to-be-accessed address (step E3). The disk control unit 21 executes an actual access to the to-be-accessed address that is determined in step E2 or step E3 (step E4).

Hereinafter, only parts of the operation, which are different from the operation of the computer system of the first embodiment, will be described.

Journal data, which is used for the commit process, checkpoint process and recovery process, is stored in the journal file that is present on the disk 23. This is equivalent to the case where the journal data, which is stored in the nonvolatile memory medium 22 in the first embodiment, is moved to the disk 23. Since the nonvolatility of the file on the disk 23 is maintained, the same reliability as in the above-described case is ensured.

The computer system of the second embodiment differs from the computer system of the first embodiment with respect to the process of reflecting journal data on the disk 23 in the checkpoint process.

In the checkpoint process, the disk control unit 21 registers on the conversion map 24 a pair of a logical address, which corresponds to an address stored in the header with respect to each of the journal data of the journal file, and a physical address, which corresponds to an address on the disk 23 that is stored in the body of the journal (this process is executed in step B3 in FIG. 4).

In short, only by operating the conversion map 24, can the data on the journal file be registered as actual data on the disk, without the need to execute new data write or copy. From the standpoint of reduction in data transfer between the host computer 1 and disk apparatus 2, the computer system of the second embodiment is similar to the computer system of the first embodiment. However, the amount of data write to the disk 23 within the disk apparatus 2 can be reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A computer system including a disk apparatus and a host computer including a journal file system which records a journal in the disk apparatus in a pre-process, the journal including update data for ensuring data integrity on the disk apparatus when the data on the disk apparatus is updated,
the disk apparatus comprising:
a memory unit which is capable of permanently storing the journal;
a storing control unit configured to store a journal, which is sent from the host computer, in the memory unit; and
an updating unit configured to execute data update corresponding to the journal stored in the memory unit in accordance with an instruction from the host computer, and
the journal file system of the host computer comprising:
a writing unit configured to execute, each time the data on the disk apparatus is updated, writing of a journal, which corresponds to the data update, to the disk apparatus; and
an informing unit configured to inform the disk apparatus of an instruction to execute the data update corresponding to the written journal.

2. A computer system including a disk apparatus and a host computer including a journal file system which records a journal in the disk apparatus in a pre-process, the journal including update data for ensuring data integrity on the disk apparatus when the data on the disk apparatus is updated,
the disk apparatus comprising:
a conversion map which stores correspondency between a logical address on a disk and a physical address on the disk;
a storing control unit configured to store a journal, which is sent from the host computer, in an empty area on the disk, on which data update corresponding to the journal is executed; and
an operating unit configured to operate the conversion map based on an instruction from the host computer, in order to change the update data which is included in the journal stored in the empty area on the disk into actual update data, and
the journal file system of the host computer comprising:
a writing unit configured to execute, each time the data on the disk apparatus is updated, writing of a journal, which corresponds to the data update, to the disk apparatus; and
an informing unit configured to inform the disk apparatus of an instruction to execute the data update corresponding to the written journal.

3. A disk apparatus comprising:
a memory unit which is capable of permanently storing a journal including update data, which is recorded in a pre-process at a time of data update, thereby to ensure data integrity;
a storing control unit configured to store a journal, which is sent from a host computer, in the memory unit; and
an updating unit configured to execute data update corresponding to the journal stored in the memory unit in accordance with an instruction from the host computer.

4. The disk apparatus according to claim 3, further comprising assigning unit configured to dynamically assign a cache area for disk access to an area on the memory unit where the journal is stored.

5. A disk apparatus comprising:
a conversion map which stores correspondency between a logical address on a disk and a physical address on the disk;
a storing control unit configured to store a journal, which is sent from the host computer, in an empty area on the disk, on which data update corresponding to the journal is executed, the journal including update data, which is recorded in a pre-process at a time of data update, thereby to ensure data integrity; and
an operating unit configured to operate the conversion map based on an instruction from the host computer, in order to change the update data which is included in the journal stored in the empty area into actual update data.

6. A data update control method for a computer system including a disk apparatus which includes a memory unit capable of permanently storing data, and a host computer including a journal file system which records a journal in the disk apparatus in a pre-process, the journal including update data for ensuring data integrity on the disk apparatus when the data on the disk apparatus is updated, the method comprising:
executing, each time the data is updated, write of a journal, which corresponds to the data update, to the disk apparatus; and
causing the disk apparatus to execute the data update corresponding to the written journal in the memory unit.

7. A data update control method for a computer system comprising a disk apparatus which includes a conversion map that stores correspondency between a logical address on a disk and a physical address on the disk, and a host computer including a journal file system which records a journal in the disk apparatus in a pre-process, the journal including update data for ensuring data integrity on the disk apparatus when the data on the disk apparatus is updated, the method comprising:
storing, each time the data is updated, a journal which corresponds to the data update in an empty area of the disk apparatus; and
operating the conversion map in order to change the update data which is included in the journal stored in the empty area into actual update data.
